(19) United States
(12) Patent Application Publication
(10) Pub. No.: US 2024/0291452 A1
(43) Pub. Date: Aug. 29, 2024

(54) RADIO FREQUENCY FRONT-END MODULE

(71) Applicant: RADROCK (SHENZHEN) TECHNOLOGY CO., LTD., Shenzhen, Guangdong (CN)

(72) Inventors: Yuan Cao, Shenzhen, Guangdong (CN); Xinghua Rong, Shenzhen, Guangdong (CN); Chuanqiu Lei, Shenzhen, Guangdong (CN); Yongjian Lei, Shenzhen, Guangdong (CN); Jianxing Ni, Shenzhen, Guangdong (CN)

(21) Appl. No.: 18/572,806

(22) PCT Filed: Jun. 13, 2022
(86) PCT No.: PCT/CN2022/098312

§ 371 Date: Dec. 21, 2023

(30) Foreign Application Priority Data
Jun. 30, 2021 (CN) 202110744177.2
Jul. 8, 2021 (CN) 202110775007.0

(51) Int. Cl. H03F 3/45; H03F 3/24; H03F 3/26; H04B 1/40

(52) U.S. Cl. CPC H03F 3/45475; H03F 3/245; H03F 3/26; H03F 2200/451; H04B 1/40

(57) ABSTRACT

The application discloses an RF front-end module, comprising a conversion transformer, the conversion transformer comprises a primary winding and a secondary winding located on the same metal layer of a substrate; a first primary coil and first secondary coil are coupled to form a first coupling coil, and a second primary coil and second secondary coil are coupled to form a second coupling coil; when the current direction of the side adjacent to the second coupling coil in the first coupling coil is the same as that of the side adjacent to the first coupling coil in the second coupling coil, the first coupling coil and the second coupling coil are arranged adjacent to each other; when these two current directions are opposite to each other, the first coupling coil and the second coupling coil are arranged away from each other.

The present application claims the benefits of Chinese Patent Application No. 202110744177.2, filed on Jun. 30, 2021, titled “RF front-end module”, and Chinese Patent Application No. 202110775007.0, filed on Jul. 8, 2021, titled “RF front-end module”.

### TECHNICAL FIELD

The application relates to the technical field of radio frequency (RF), in particular to an RF front-end module.

### BACKGROUND

RF front-end is between antenna and RF transceiver, and it is the core component of electronic end communication. Push-pull power amplifier is widely used because it can meet the requirements of higher frequency, wider bandwidth and higher-order QAM modulation in an RF front-end. Transformers are usually used in push-pull power amplifiers, which occupy a large volume. In some applications, transformers would be placed on substrate. However, in some specific applications, the area or layer number of the substrate is limited, it is difficult to give consideration to both the area and performance of the transformer with this limited substrate area or layer number, which restricts the overall performance metrics of the push-pull power amplifier.

### SUMMARY

The embodiment of the application provides an RF front-end module, aiming at solving the problem that, for the design of transformer in push-pull amplifier, it is difficult to give consideration to both transformer area and performance because of the restriction of substrate area or the number of substrate layer.

An RF front-end module is provided, including a substrate and a push-pull power amplifier circuit, wherein the push-pull power amplifier circuit includes a conversion transformer, the conversion transformer includes a primary winding and a secondary winding located on a same metal layer of the substrate;
the primary winding includes a first primary coil and a second primary coil;
the secondary winding includes a first secondary coil and a second secondary coil;
the first primary coil and the first secondary coil are coupled to form a first coupling coil, and the second primary coil and the second secondary coil are coupled to form a second coupling coil;
if a current direction of a side adjacent to the second coupling coil in the first coupling coil is the same as that of a side adjacent to the first coupling coil in the second coupling coil, the first coupling coil and the second coupling coil are arranged adjacent to each other; and
if a current direction of a side adjacent to the second coupling coil in the first coupling coil is opposite to that of a side adjacent to the first coupling coil in the second coupling coil, the first coupling coil and the second coupling coil are arranged away from each other.

Further, both the primary winding and the secondary winding are windings formed by a single transmission line; or, one of the primary winding and the secondary winding is a winding formed by a single transmission line, and another one is a winding formed by connecting a first transmission line and a second transmission line; the first transmission line is positioned in the first coupling coil, and the second transmission line is positioned in the second coupling coil.

Further, the primary winding includes a primary transmission line, one part of the primary transmission line forms the first primary coil and another part forms the second primary coil; starting from a first end of the primary transmission line, a routing direction of the first primary coil is a first direction, and starting from a second end of the primary transmission line, a routing direction of the second primary coil is a second direction;
the secondary winding includes a secondary transmission line, one part of the secondary transmission line forms the first secondary coil and another part forms the second secondary coil; starting from a first end of the secondary transmission line, a routing direction of the first secondary coil is the first direction, and starting from a second end of the secondary transmission line, a routing direction of a second secondary coil is the second direction; and
the first direction is opposite to the second direction, and the first coupling coil and the second coupling coil are arranged away from each other.

Further, the primary winding includes a first primary transmission line and a second primary transmission line; the first primary transmission line includes a first end and a second end, the second primary transmission line includes a third end and a fourth end, and the second end of the first primary transmission line is connected with the third end of the second primary transmission line; the first primary transmission line forms the first primary coil; and the second primary transmission line forms the second primary coil;
starting from the second end of the first primary transmission line, a routing direction of the first primary coil is a first direction, and starting from the third end of the second primary transmission line, a routing direction of the second primary coil is a second direction;
the secondary winding includes a secondary transmission line, one part of the secondary transmission line forms the first secondary coil and another part forms the second secondary coil; starting from a first end of the secondary transmission line, a routing direction of the first secondary coil is the first direction, and starting from a second end of the secondary transmission line, a routing direction of a second secondary coil is the second direction; and
the first direction is opposite to the second direction, and the first coupling coil and the second coupling coil are arranged away from each other.

Further, the second end of the first primary transmission line and the third end of the second primary transmission line are electrically connected by a first bonding wire.

Further, the primary winding includes a primary transmission line, one part of the primary transmission line forms the first primary coil and another part forms the second primary coil; starting from a first end of the primary transmission line, a routing direction of the first primary coil is a first direction, and starting from a second end of the primary transmission line, a routing direction of the second primary coil is a second direction;
the secondary winding includes a first secondary transmission line and a second secondary transmission line, and the first secondary transmission line includes a first end and a second end; the second secondary transmission line includes a third end and a fourth end; the first secondary transmission line forms the first secondary coil, and the second secondary transmission line forms the second secondary coil; starting from the second end of the first secondary transmission line, a routing direction of the first secondary coil is a first direction, starting from the third end of the second secondary transmission line, a routing direction of the second secondary coil is a second direction; and
the first direction and the second direction are the same, and the first coupling coil and the second coupling coil are arranged adjacent to each other.

Further, the second end of the first secondary transmission line and the third end of the second secondary transmission line are electrically connected by a second bonding wire.

Further, the first direction is clockwise and the second direction is counterclockwise; or the first direction is counterclockwise and the second direction is clockwise.

Further, the push-pull power amplifier circuit further includes a first differential amplifier branch and a second differential amplifier branch;
the first end of the primary winding is connected with an output end of the first differential amplifier branch, and the second end of the primary winding is connected with an output end of the second differential amplifier branch; and
the first end of the secondary winding is connected with a signal output end, and the second end of the secondary winding is connected with a ground end or a power supply end.

Further, the push-pull power amplifier circuit further includes a first differential amplifier branch and a second differential amplifier branch;
the first end of the secondary winding is connected with an input end of the first differential amplifier branch, and the second end of the secondary winding is connected an input end of the second differential amplifier branch; and
the first end of the primary winding is connected with a signal input end, and the second end of the primary winding is connected with a ground end or a power supply end.

Further, the RF front-end module further includes a feedback power;
if the current direction of a side adjacent to the second coupling coil in the first coupling coil is opposite to that of a side adjacent to the first coupling coil in the second coupling coil, the feedback power is arranged between the first coupling coil and the second coupling coil, and is coupled to the primary winding through a transmission line.

The embodiment of the application also provides an RF front-end module, including a substrate and a push-pull power amplifier circuit, wherein the push-pull power amplifier circuit includes a first differential amplifier branch, a second differential amplifier branch and a conversion transformer;
the conversion transformer includes a primary winding and a secondary winding located on a same metal layer of the substrate;
the first differential amplifier branch includes a first power amplifier and a first capacitor, and the second differential amplifier branch includes a second power amplifier and a second capacitor;
an output end of the first power amplifier is connected with a first end of the primary winding via the first capacitor; an output end of the second power amplifier is connected with a second end of the primary winding via the second capacitor;
a first feedback power end is coupled to the output end of the first power amplifier via a first inductor, and a second feedback power end is coupled to the output end of the second power amplifier via a second inductor;
the primary winding includes a first primary coil and a second primary coil;
the secondary winding includes a first secondary coil and a second secondary coil;
the first primary coil and the first secondary coil are coupled to form a first coupling coil, and the second primary coil and the second secondary coil are coupled to form a second coupling coil;
if a current direction of a side adjacent to the second coupling coil in the first coupling coil is the same as that of a side adjacent to the first coupling coil in the second coupling coil, the first coupling coil and the second coupling coil are arranged adjacent to each other; and
if a current direction of a side adjacent to the second coupling coil in the first coupling coil is opposite to that of a side adjacent to the first coupling coil in the second coupling coil, the first coupling coil and the second coupling coil are arranged away from each other.

Further, both the primary winding and the secondary winding are windings formed by a single transmission line; or, one of the primary winding and the secondary winding is a winding formed by a single transmission line, and another one is a winding formed by connecting a first transmission line and a second transmission line; the first transmission line is positioned in the first coupling coil, and the second transmission line is positioned in the second coupling coil.

The embodiment of the application provides an RF front-end module, including a substrate and a push-pull power amplifier circuit arranged on the substrate, the push-pull power amplifier circuit includes a conversion transformer, the conversion transformer includes a primary winding and a secondary winding located on the same metal layer of the substrate; the primary winding includes a first primary coil and a second primary coil; the secondary winding includes a first secondary coil and a second secondary coil; the first primary coil and the first secondary coil are coupled to form a first coupling coil, and the second primary coil and the second secondary coil are coupled to form a second coupling coil; when the current direction of the side adjacent to the second coupling coil in the first coupling coil is the same as that of the side adjacent to the first coupling coil in the second coupling coil, the first coupling coil and the second coupling coil are arranged adjacent to each other; when the current direction of the side adjacent to the second coupling coil in the first coupling coil is opposite to that of the side adjacent to the first coupling coil in the second coupling coil, the first coupling coil and the second coupling coil are arranged away from each other. In the push-pull power amplifier circuit of the present application, the primary winding and the secondary winding of the conversion transformer are arranged on the same metal layer of the substrate, the primary winding and secondary winding form a separated double coupling coil, thus reducing the occupied area and layers of the conversion transformer on the substrate. And when the current direction of the side adjacent to the second coupling coil in the first coupling coil is the same as that of the side adjacent to the first coupling coil in the second coupling coil, the first coupling coil and the second coupling coil are arranged adjacent to each other, so that the coupling degree of the conversion transformer is improved and the occupied area of the conversion transformer on the substrate is further reduced. When the current direction of the side adjacent to the second coupling coil in the first coupling coil is opposite to that of the side adjacent to the first coupling coil in the second coupling coil, the first coupling coil and the second coupling coil are arranged away from each other, so that the coupling degree between the primary winding and secondary winding is prevented from being affected by mutual counteraction of currents. In this way, not only the coupling degree of the conversion transformer can be improved, but also the flexibility of the arrangement of the first coupling coil and second coupling coil can be improved. It can be understood that, for the conversion transformer in the push-pull power amplifier circuit of the present application, with the arrangement of the primary winding and secondary winding on the same metal layer of the substrate, the primary winding and the secondary winding form a separated double coupling coil. And the positions of the first coupling coil and second coupling coil can be flexibly arranged according to the current direction of the side adjacent to the second coupling coil in the first coupling coil and the current direction of the side adjacent to the first coupling coil in the second coupling coil. Therefore, while reducing the occupied area of the transformer in the push-pull amplifier, the coupling degree and design flexibility of the conversion transformer can be improved, so that the push-pull power amplifier circuit can support a larger bandwidth. In this way, the problem that the design of the transformer in the push-pull amplifier is difficult to give consideration to both the area and performance of the transformer because of the restriction of the substrate area or the number of substrate layers is solved.

This embodiment also provides an RF front-end module. For the push-pull power amplifier circuit, with the arrangement of the primary winding and secondary winding on the same metal layer of the substrate, the primary winding and the secondary winding form a separated double coupling coil. And the positions of the first coupling coil and second coupling coil can be flexibly arranged according to the current direction of the side adjacent to the second coupling coil in the first coupling coil and the current direction of the side adjacent to the first coupling coil in the second coupling coil. Therefore, while reducing the occupied area of the transformer in the push-pull amplifier, the coupling degree and design flexibility of the conversion transformer can be improved, so that the push-pull power amplifier circuit can support a larger bandwidth. In this way, the problem that the design of the transformer in the push-pull amplifier is difficult to give consideration to both the area and performance of the transformer because of the restriction of the substrate area or the number of substrate layers is solved. In addition, as the output end of the first power amplifier in this embodiment is connected with the first end of the primary winding of the conversion transformer via a first capacitor; and the output end of the second power amplifier is connected with the second end of the primary winding of the conversion transformer via a second capacitor, the first capacitor and the second capacitor can provide a part of impedance conversion. That is, the first capacitor, second capacitor and conversion transformer jointly participate in the impedance conversion of the push-pull power amplifier circuit to realize impedance matching. Thus, the push-pull power amplifier circuit of this embodiment is a two-order matching push-pull power amplifier circuit, compared with one-order matching push-pull power amplifier circuit (for example, push-pull power amplifier circuit with balun for impedance conversion alone), it can not only improve the bandwidth performance of fundamental impedance of push-pull power amplifier circuit, but also the turns ratio of conversion transformer is designed more flexibly. And since the first feedback power end in this embodiment is coupled to the output end of the first power amplifier via the first inductor, and the second feedback power end is coupled to the output end of the second power amplifier via the second inductor. That is, the DC signals provided by the first feedback power end and the second feedback power end do not need to pass through the coils in the conversion transformer, and no DC signals pass through the coils in the conversion transformer. Compared with transmitting the feed signal provided by the feedback power to the first power amplifier and the second power amplifier through the conversion transformer, the width of the coil of the conversion transformer in this embodiment can be designed to be narrower. Therefore, when the conversion transformer is arranged in a single-layer substrate, the coupling degree between the primary winding and secondary winding of the conversion transformer can be further improved and the area of the conversion transformer can be reduced, so as to further optimize the overall performance of the push-pull power amplifier circuit.

### BRIEF DESCRIPTION OF THE DRAWINGS

In order to explain the technical solution of the embodiments of this application more clearly, the drawings described in the description of the embodiments of this application will be briefly introduced below. Obviously, the drawings in the present application and their accompanying detailed description are directed to merely exemplary embodiments of the application. For those of ordinary skill in this field, other drawings may be obtained according to these drawings without any creative effort.

FIG. 1 is a schematic circuit diagram of a RF front-end module according to an embodiment of the present application.

FIG. 2 is a structural diagram of a conversion transformer according to an embodiment of the present application.

FIG. 3 is another structural diagram of a conversion transformer according to an embodiment of the present application.

FIG. 4 is another structural diagram of a conversion transformer according to an embodiment of the present application.

FIG. 5 is another structural diagram of a conversion transformer according to an embodiment of the present application.

FIG. 6 is another structural diagram of a conversion transformer according to an embodiment of the present application.

FIG. 7 is another structural schematic diagram of an RF front-end module according to an embodiment of the present application.

FIG. 8 is another structural schematic diagram of an RF front-end module according to an embodiment of the present application.

FIG. 9 is another structural schematic diagram of an RF front-end module according to an embodiment of the present application.

Reference signs in the figures are as follows: 10. Primary winding; 11. First primary coil; 12. Second primary coil; 13. Primary transmission line; 131. First primary transmission line; 132. Second primary transmission line; 20. Secondary winding; 21. First secondary coil; 22. Second secondary coil; 23. Secondary transmission line; 231. First secondary transmission line; 232. Second secondary transmission line; 31. First bonding wire; 32. Second bonding wire; 100. Push-pull power amplifier circuit; 101. First differential amplifier branch; 102. Second differential amplifier branch; 103. Conversion transformer; 200. Substrate.

### DETAILED DESCRIPTION OF DISCLOSED EMBODIMENTS

In order to make the technical problems, technical solutions and beneficial effects of the present application more clear, the application will be further explained in detail below with reference to the drawings and embodiments. It should be understood that the specific embodiments described here are only used to illustrate the application, rather than to limit the application.

In the description of the present application, it is to be understood that the terms “longitudinal”, “radial”, “length”, “width”, “thickness”, “upper”, “lower”, “front”, “rear”, “left”, “right”, “vertical”, “horizontal”, “top”, “bottom”, “inner”, “outer”, and the like indicate an orientation or positional relationship based on that shown in the drawings, and are for convenience of description and simplicity of description only, not intended to indicate or imply that the indicated devices or elements must have a particular orientation, be constructed and operated in a particular orientation, and are therefore not to be construed as limiting the present application.

In the description of the present application, unless otherwise stated, “multiple” means two or more. In the description of the present application, it should be noted that unless otherwise specified and defined, the terms “installation”, “connected with” and “connected to” should be understood in a broad sense. For example, they may be fixedly connected, detachably connected or integrally connected, or may be mechanically connected or electrically connected, or may be directly connected or indirectly connected through an intermediate medium. Or it may be internal communication of two elements. For those of ordinary skill in the art, the specific meanings of the above terms in the present application may be understood in specific situations.

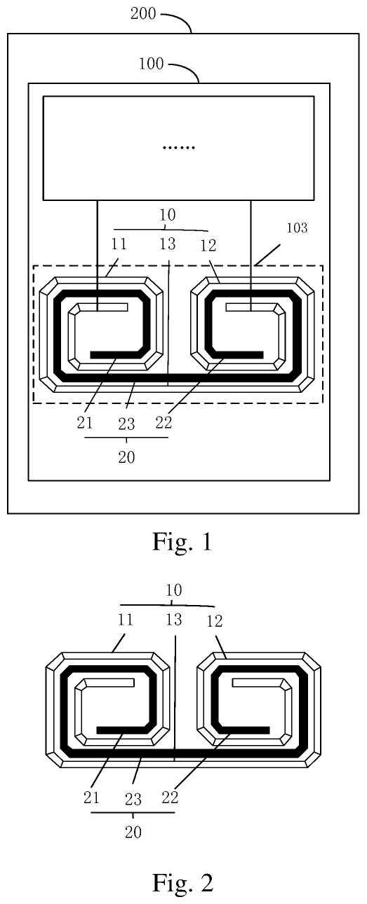

This embodiment provides an RF front-end module, as shown in FIG. 1, which includes a substrate 200 and a push-pull power amplifier circuit 100, and the push-pull power amplifier circuit 100 includes a conversion transformer 103. The conversion transformer 103 includes a primary winding 10 and a secondary winding 20 located in the same metal layer of substrate 200. The primary winding 10 includes a first primary coil 11 and a second primary coil 12. The secondary winding 20 includes a first secondary coil 21 and a second secondary coil 22. The first primary coil 11 and first secondary coil 21 are coupled to form a first coupling coil, and the second primary coil 12 and second secondary coil 22 are coupled to form a second coupling coil. If the current direction of the side adjacent to the second coupling coil in the first coupling coil is the same as that of the side adjacent to the first coupling coil in the second coupling coil, the first coupling coil and the second coupling coil are arranged adjacent to each other. If the current direction of the side adjacent to the second coupling coil in the first coupling coil is opposite to the current direction of the side adjacent to the first coupling coil in the second coupling coil, the first coupling coil and the second coupling coil are arranged away from each other.

As an example, if the current direction of the side adjacent to the second coupling coil in the first coupling coil is the same as that of the side adjacent to the first coupling coil in the second coupling coil, the first coupling coil and the second coupling coil are arranged adjacent to each other. And, the minimum distance between the first coupling coil and the second coupling coil is about the width of one coil.

As an example, if the current direction of the side adjacent to the second coupling coil in the first coupling coil is opposite to that of the side adjacent to the first coupling coil in the second coupling coil, the first coupling coil and the second coupling coil are arranged away from each other. And, the maximum distance between the first coupling coil and the second coupling coil is about the width of four coils.

Specifically, the RF front-end module includes a substrate 200 and a push-pull power amplifier circuit 100 arranged on the substrate 200. Optionally, the substrate 200 is provided with at least two metal layers. At least one metal layer is used to place the primary winding 10 and the secondary winding 20 in the conversion transformer 103, and the other metal layer is used as a ground layer. The push-pull power amplifier circuit 100 is configured to amplify an RF input signal.

As an example, the push-pull power amplifier circuit 100 includes a conversion transformer 103. Optionally, the conversion transformer 103 may be arranged at the input stage of the push-pull power amplifier circuit 100, and is used for converting the RF input signal and then inputting the converted RF signal to the latter stage circuit (for example, a differential amplifier circuit). The conversion transformer 103 may also be arranged at the output stage of the push-pull power amplifier circuit 100, and is used for converting and synthesizing the RF amplified signal processed by the differential amplifier circuit.

The conversion transformer 103 includes a primary winding 10 and a secondary winding 20. In a specific implementation, when the conversion transformer 103 is arranged at the input stage of the push-pull power amplifier circuit 100, the input impedance of the push-pull power amplifier circuit 100 can be converted to realize impedance matching by adjusting the turns ratio of the primary winding 10 and secondary winding 20. In another specific implementation, when the conversion transformer 103 is arranged at the output stage of the push-pull power amplifier circuit 100, the output impedance of the push-pull power amplifier circuit 100 can be converted to realize impedance matching by adjusting the turns ratio of the primary winding 10 and secondary winding 20.

In this embodiment, the primary winding 10 and the secondary winding 20 are arranged on the same metal layer of the substrate 200. For example, the substrate 200 in this embodiment includes a first metal layer and a second metal layer, and both the primary winding 10 and the secondary winding 20 are arranged on the first metal layer, and the second metal layer is used as a ground layer; the primary winding 10 includes a first primary coil 11 and a second primary coil 12, and the secondary winding 20 includes a first secondary coil 21 and a second secondary coil 22. The first primary coil 11 and first secondary coil 21 are coupled to form a first coupling coil, the second primary coil 12 and second secondary coil 22 are coupled to form a second coupling coil; and the first coupling coil and second coupling coil form a double coupling coil. Traditionally, the primary winding 10 and the secondary winding 20 are directly arranged on different metal layers of the substrate 200, and only a coupling coil is formed between the primary winding 10 and the secondary winding 20. In contrast, for the conversion transformer 103 in the push-pull power amplifier circuit 100 provided by the present application, by arranging the primary winding 10 and the secondary winding 20 on the first metal layer and forming a double coupling coil, not only can the occupied area and the number of layers on the substrate 200 be reduced, but also the overall performance applied to the push-pull power amplifier circuit 100 can be improved.

As an example, optionally, the number of turns of the first primary coil 11, the number of turns of the second primary coil 12, the number of turns of the first secondary coil 21 and the number of turns of the second secondary coil 22 may be adjusted according to actual needs. For example, according to the impedance conversion in the push-pull power amplifier circuit 100, the turns ratio of the first primary coil 11 and the second primary coil 12 to the first secondary coil 21 and the second secondary coil 22 is adjusted.

In a specific embodiment, when the current direction of the side adjacent to the second coupling coil in the first coupling coil is the same as that of the side adjacent to the first coupling coil in the second coupling coil, the current of the side adjacent to the second coupling coil in the first coupling coil and the current of the side adjacent to the first coupling coil in the second coupling coil are superimposed on each other. Therefore, by arranging the first coupling coil and the second coupling coil adjacent to each other, not only can the occupied area of the conversion transformer 103 on the substrate 200 be reduced, but also the coupling degree between the primary winding 10 and the secondary winding 20 can be further improved. Thereby improving the coupling degree and overall performance of the conversion transformer 103 applied to the push-pull power amplifier circuit 100, and enabling the push-pull power amplifier circuit 100 to support a larger bandwidth. Furthermore, it solves the problem that the design of transformer in push-pull amplifier is difficult to give consideration to both transformer area and performance because of the restriction of area or layer of the substrate 200.

In another specific embodiment, when the current direction of the side adjacent to the second coupling coil in the first coupling coil is opposite to that of the side adjacent to the first coupling coil in the second coupling coil, the current of the side adjacent to the second coupling coil in the first coupling coil and the current of the side adjacent to the first coupling coil in the second coupling coil cancel each other out. Therefore, by arranging the first coupling coil and the second coupling coil away from each other, the mutual cancellation of currents can be avoided to affect the coupling degree between the primary winding 10 and the secondary winding 20. Thereby improving the coupling degree between the primary winding 10 and the secondary winding 20, and further improving the overall coupling degree of the conversion transformer 103 in the push-pull power amplifier circuit 100, so that the push-pull power amplifier circuit 100 can support a larger bandwidth.

It can be seen from this that the conversion transformer 103 in the push-pull power amplifier circuit 100 of the present application can determine the current direction of the side adjacent to the second coupling coil in the first coupling coil, and the positions of the first coupling coil and the second coupling coil are flexibly arranged according to the current direction of the side adjacent to the first coupling coil in the second coupling coil. It can also improve the coupling degree and design flexibility of the conversion transformer 103, so that the push-pull power amplifier circuit 100 can support a larger bandwidth.

As an example, the push-pull power amplifier circuit 100 generally further includes a differential amplifier circuit, and the conversion transformer 103 may be arranged at the output end of the differential amplifier circuit as an output stage conversion circuit of the push-pull power amplifier circuit 100; or, the conversion transformer 103 may also be arranged at the input end of the differential amplifier circuit as an input stage conversion circuit of the push-pull power amplifier circuit 100.

In a specific embodiment, the conversion transformer 103 is arranged at the output end of the differential amplifier circuit as an output stage conversion circuit of the push-pull power amplifier circuit 100. Specifically, a first output end of the differential amplifier circuit is connected to a first input end of the primary winding 10, a second output end of the differential amplifier circuit is connected to a second input end of the primary winding 10, a first output end of the secondary winding 20 is connected to the signal output end Vout, and a second output end of the secondary winding 20 is connected to the ground. The conversion transformer 103 is configured to convert and synthesize a first RF amplified signal and a second RF amplified signal output by the differential amplifier circuit, and output the RF output signal to the signal output end Vout.

In another specific embodiment, the conversion transformer 103 may also be arranged at the input end of the differential amplifier circuit as an input stage conversion circuit of the push-pull power amplifier circuit 100. Specifically, the first input end of the primary winding 10 is connected to the signal input end Vin, the second input end of the primary winding 10 is connected to the ground, the first output end of the secondary winding 20 is connected to a first input end of the differential amplifier circuit, and the second output end of the secondary winding 20 is connected to a second input end of the differential amplifier circuit. The conversion transformer 103 is configured to convert the RF input signal input from the signal input end Vin, output a first RF signal to the first input end of the differential amplifier circuit, and output a second RF signal to the second input end of the differential amplifier circuit.

In this embodiment, the RF front-end module includes a substrate 200 and a push-pull power amplifier circuit 100 arranged on the substrate 200. The push-pull power amplifier circuit 100 includes a conversion transformer 103. The conversion transformer 103 includes a primary winding 10 and a secondary winding 20 located at the same metal layer of the substrate 200. The primary winding 10 includes a first primary coil 11 and a second primary coil 12. The secondary winding 20 includes a first secondary coil 21 and a second secondary coil 22. The first primary coil 11 and first secondary coil 21 are coupled to form a first coupling coil, and the second primary coil 12 and second secondary coil 22 are coupled to form a second coupling coil. When the current direction of the side adjacent to the second coupling coil in the first coupling coil is the same as that of the side adjacent to the first coupling coil in the second coupling coil, the first coupling coil and the second coupling coil are arranged adjacent to each other. When the current direction of the side adjacent to the second coupling coil in the first coupling coil is opposite to that of the side adjacent to the first coupling coil in the second coupling coil, the first coupling coil and the second coupling coil are arranged away from each other. In the push-pull power amplifier circuit 100 of the present application, the primary winding 10 and the secondary winding 20 of the conversion transformer 103 are arranged on the same metal layer of the substrate 200, and the primary winding 10 and secondary winding 20 form a separated double coupling coil, thus reducing the occupied area and the number of layers of the conversion transformer 103 on the substrate 200. Moreover, when the current direction of the side adjacent to the second coupling coil in the first coupling coil is the same as that of the side adjacent to the first coupling coil in the second coupling coil, the first coupling coil and the second coupling coil are arranged adjacent to each other, which further reduces the area occupied by the conversion transformer 103 on the substrate 200 while improving the coupling degree of the conversion transformer 103. When the current direction of the side adjacent to the second coupling coil in the first coupling coil is opposite to that of the side adjacent to the first coupling coil in the second coupling coil, the first coupling coil and the second coupling coil are arranged away from each other, so that the situation that the mutual cancellation of currents affects the coupling degree between the primary winding 10 and secondary winding 20 can be avoided. Therefore, not only the coupling degree of the conversion transformer 103 can be improved, but also the flexibility of the arrangement of the first coupling coil and second coupling coil can be improved. It can be understood that, for the conversion transformer 103 of the push-pull power amplifier circuit 100, with the arrangement of the primary winding 10 and secondary winding 20 on the same metal layer of the substrate 200, the primary winding 10 and the secondary winding 20 form a separated double coupling coil. And the positions of the first coupling coil and second coupling coil can be flexibly arranged according to the current direction of the side adjacent to the second coupling coil in the first coupling coil and the current direction of the side adjacent to the first coupling coil in the second coupling coil. Therefore, while reducing the occupied area of the transformer in the push-pull amplifier, the coupling degree and design flexibility of the conversion transformer 103 can be improved, so that the push-pull power amplifier circuit 100 can support a larger bandwidth. In this way, the problem that the design of the transformer in the push-pull amplifier is difficult to give consideration to both the area and performance of the transformer because of the restriction of the area or number of layers of the substrate 200 is solved.

In an embodiment, as shown in FIGS. 2 to 5, both the primary winding 10 and the secondary winding 20 are windings formed by a single transmission line, or one of the primary winding 10 and the secondary winding 20 is a winding formed by a single transmission line, the other one is formed by a first transmission line and a second transmission line. And the first transmission line is positioned in the first coupling coil and the second transmission line is positioned in the second coupling coil.

Understandably, the first transmission line in the first coupling coil and the second transmission line in the second coupling coil are two separate transmission lines. In a specific embodiment, the first transmission line and the second transmission line may be connected by bonding wire or binding wire.

As an example, as shown in FIG. 2, the primary winding 10 is a winding formed by a single transmission line, and the secondary winding 20 is a winding formed by a single transmission line. For example, the primary winding 10 is a winding formed by a primary transmission line 13, and the secondary winding 20 is a winding formed by a secondary transmission line 23. A part of the primary transmission line 13 forms the first primary coil 11, another part forms the second primary coil 12; and a part of the secondary transmission line 23 forms the first secondary coil 21, another part forms the second secondary coil 22.

In a specific embodiment, the push-pull power amplifier circuit 100 usually further includes a differential amplifier circuit. If the conversion transformer 103 is an output stage conversion circuit arranged in the push-pull power amplifier circuit 100, a first end of the primary transmission line 13 of the conversion transformer 103 is connected to the first output end of the differential amplifier circuit, a second end of the primary transmission line 13 is connected to the second output end of the differential amplifier circuit; a first end of the secondary transmission line 23 is connected to the signal output end Vout, and a second end is connected to the ground or the power supply. The conversion transformer 103 is configured to convert and synthesize a first RF amplified signal and a second RF amplified signal output by the differential amplifier circuit, and output the RF output signal to the signal output end Vout.

If the conversion transformer 103 is a conversion circuit arranged at the input stage of the push-pull power amplifier circuit 100, the first end of the primary transmission line 13 of the conversion transformer 103 is connected to the signal input end Vin, the second end of the primary transmission line 13 is connected to the ground or the power supply; the first end of the secondary transmission line 23 is connected to the first input end of the differential amplifier circuit, and the first end of the secondary transmission line 23 is connected to the second input end of the differential amplifier circuit.

As another example, as shown in FIG. 4 and FIG. 5, the primary winding 10 is a winding formed by a single transmission line, and the secondary winding 20 is a winding formed by a first transmission line and a second transmission line. And the first transmission line is positioned in the first coupling coil and the second transmission line is positioned in the second coupling coil. For example, the primary winding 10 is a winding formed by a primary transmission line 13, and the secondary winding 20 is a winding formed by a first secondary transmission line 231 and a second secondary transmission line 232. Part of the primary transmission line 13 forms the first primary coil 11 and the other part forms the second primary coil 12. The first secondary transmission line 231 forms the first secondary coil 21, which is positioned in the first coupling coil; and the second secondary transmission line 232 forms the second secondary coil 22, which is positioned in the second coupling coil.

In a specific embodiment, if the conversion transformer 103 is a conversion circuit arranged at the output stage of the push-pull power amplifier circuit 100, the primary transmission line 13 of the conversion transformer 103 includes a first end and a second end. The first end of the primary transmission line 13 is connected with the first output end of the differential amplifier circuit, and the second end of the primary transmission line 13 is connected with the second output end of the differential amplifier circuit. The first secondary transmission line 231 includes a first end and a second end. The second secondary transmission line 232 includes a third end and a fourth end. The first end of the first secondary transmission line 231 is connected to the signal output end Vout, and the fourth end of the second secondary transmission line 232 is connected to the ground. The second end of the first secondary transmission line 231 and the third end of the second secondary transmission line 232 may be electrically connected via a first bonding wire 31.

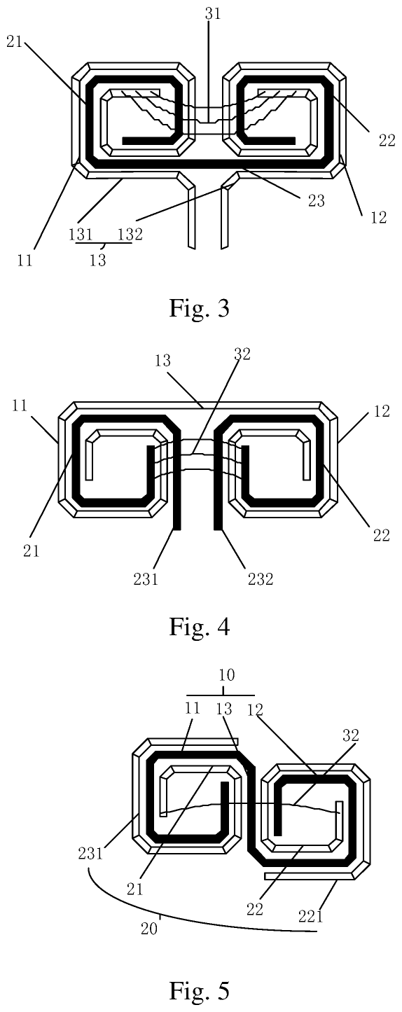

As another example, as shown in FIG. 3, the primary winding 10 is a winding formed by two transmission lines, and the secondary winding 20 is a winding formed by a single transmission line. For example, the primary winding 10 is a winding formed by a first primary transmission line 131 and a second primary transmission line 132, and the secondary winding 20 is a winding formed by the secondary transmission line 23. The first primary transmission line 131 forms the first primary coil 11, positioned in the first coupling coil; and the second primary transmission line 132 forms the second primary coil 12, positioned in the second coupling coil. Part of the secondary transmission line 23 forms the first secondary coil 21 and the other part forms the second secondary coil 22.

If the conversion transformer 103 is a conversion circuit arranged at the output stage of the push-pull power amplifier circuit 100, the first primary transmission line 131 of the conversion transformer 103 includes a first end and a second end; the second primary transmission line 132 includes a third end and a fourth end. The first end of the first primary transmission line 131 is connected with the first output end of the differential amplifier circuit, and the second end of the second primary transmission line 132 is connected with the second output end of the differential amplifier circuit. The second end of the first primary transmission line 131 and the third end of the second primary transmission line 132 can be electrically connected via the second bonding wire 32. The first end of the secondary transmission line 23 is connected to the signal output end Vout, and the second end is connected to the ground.

In this embodiment, both the primary winding 10 and the secondary winding 20 are windings formed by a single transmission line, or one of the primary winding 10 and the secondary winding 20 is a winding formed by a single transmission line and the other one is a winding formed by two transmission lines. Various wiring or winding connection modes of the primary winding 10 and the secondary winding 20 of the conversion transformer 103 are provided, so that for application scenarios where the design of the transformer in the push-pull amplifier is restricted by the area of the substrate 200 or the number of layers of the substrate 200, the occupied area of the conversion transformer 103 can be reduced and the coupling degree of the conversion transformer 103 can be improved, thereby ensuring both the area and performance of the transformer at the same time.

In an embodiment, as shown in FIG. 2, the primary winding 10 includes a primary transmission line 13, one part of which forms a first primary coil 11 and the other part forms a second primary coil 12. Starting from a first end of the primary transmission line 13, a routing direction of the first primary coil 11 is a first direction, and starting from a second end of the primary transmission line 13, a routing direction of the second primary coil 12 is a second direction; The secondary winding 20 includes a secondary transmission line 23, one part of which forms a first secondary coil 21 and the other part forms a second secondary coil 22. Starting from a first end of the secondary transmission line 23, a routing direction of the first secondary coil 21 is the first direction, and starting from a second end of the secondary transmission line 23, a routing direction of a second secondary coil 22 is the second direction. The first direction and the second direction are opposite, and the first coupling coil and the second coupling coil are arranged away from each other.

It can be understood that the routing direction is used to describe the winding direction of the coil presented by the external structure of the coil, and is not limited to the winding direction of the coil for design or manufacture. As an example, starting from the first end of the primary transmission line 13, the winding direction of the first primary coil 11 is clockwise; starting from the second end of the primary transmission line 13, the routing direction of the second primary coil 12 is counterclockwise.

In a specific embodiment, since the first direction and the second direction are opposite, the current of the side adjacent to the second coupling coil in the first coupling coil and the current of the side adjacent to the first coupling coil in the second coupling coil cancel each other out. Therefore, by arranging the first coupling coil and the second coupling coil away from each other, the mutual cancellation of currents can be avoided to affect the coupling degree between the primary winding 10 and the secondary winding 20, thus improving the coupling degree between the primary winding 10 and the secondary winding 20.

In a specific embodiment, the primary winding 10 is formed by a single transmission line, i.e., the primary transmission line 13, one part of which forms the first primary coil 11 and the other part forms the second primary coil 12. The secondary winding 20 is formed by a single transmission line, i.e., the secondary transmission line 23, one part of which forms the first secondary coil 21 and the other part forms the second secondary coil 22.

As an example, starting from the first end of the primary transmission line 13, the routing direction of the first primary coil 11 is the first direction, and starting from the second end of the primary transmission line 13, the routing direction of the second primary coil 12 is the second direction, and the first direction and the second direction are opposite; starting from the first end of the secondary transmission line 23, the routing direction of the first secondary coil 21 is the first direction, starting from the second end of the secondary transmission line 23, the routing direction of the second secondary coil 22 is the second direction. For example, starting from the first end of the primary transmission line 13, the routing direction of the first primary coil 11 is counterclockwise; starting from the second end of the primary transmission line 13, the routing direction of the second primary coil 12 is clockwise. Alternatively, starting from the first end of the primary transmission line 13, the routing direction of the first primary coil 11 is clockwise; starting from the second end of the primary transmission line 13, the routing direction of the second primary coil 12 is counterclockwise.

For example, when the RF front-end module works, the current direction of the side adjacent to the second coupling coil in the first coupling coil is opposite to that of the side adjacent to the first coupling coil in the second coupling coil, by arranging the first coupling coil and the second coupling coil away from each other, the situation that the coupling degree between the primary winding 10 and the secondary winding 20 is affected by the mutual cancellation of the current of the side adjacent to the second coupling coil in the first coupling coil and the current of the side adjacent to the first coupling coil in the second coupling coil can be avoided. Therefore, the coupling degree of the conversion transformer 103 is further improved, the push-pull power amplifier circuit 100 is enabled to support a larger bandwidth, and at the same time, the flexibility of the arrangement of the conversion transformer 103 on the substrate 200 can be further improved.

In this embodiment, starting from the first end of the primary transmission line 13, the routing direction of the first primary coil 11 is the first direction; starting from the second end of the primary transmission line 13, the routing direction of the second primary coil 12 is the second direction; and the first direction and the second direction are opposite. Starting from the first end of the secondary transmission line 23, the routing direction of the first secondary coil 21 is the first direction; starting from the second end of the secondary transmission line 23, the routing direction of the second secondary coil 22 is the second direction; and the first direction and the second direction are opposite. By arranging the first coupling coil and the second coupling coil away from each other, the situation that the coupling degree between the primary winding 10 and the secondary winding 20 is affected by the mutual cancellation of the current of the side adjacent to the second coupling coil in the first coupling coil and the current of the side adjacent to the first coupling coil in the second coupling coil can be avoided. Therefore, the coupling degree of the conversion transformer 103 is further improved, the push-pull power amplifier circuit 100 is enabled to support a larger bandwidth, and at the same time, the flexibility of the arrangement of the conversion transformer 103 on the substrate 200 can be further improved.

In an embodiment, as shown in FIG. 3, the primary winding 10 includes a first primary transmission line 131 and a second primary transmission line 132. The first primary transmission line 131 includes a first end and a second end. The second primary transmission line 132 includes a third end and a fourth end. The second end of the first primary transmission line 131 is connected with the third end of the second primary transmission line 132. The first primary transmission line 131 forms the first primary coil 11; the second primary transmission line 132 forms the second primary coil 12. Starting from the second end of the first primary transmission line 131, the routing direction of the first primary coil 11 is the first direction, starting from the third end of the second primary transmission line 132, the routing direction of the second primary coil 12 is the second direction. The secondary winding 20 includes a secondary transmission line 23, one part of which forms the first secondary coil 21 and the other part forms a second secondary coil 22. Starting from the first end of the secondary transmission line 23, the routing direction of the first secondary coil 21 is the first direction, starting from the second end of the secondary transmission line 23, the routing direction of the second secondary coil 22 is the second direction. The first direction and the second direction are opposite, and the first coupling coil and the second coupling coil are arranged away from each other.

In a specific embodiment, the primary winding 10 is formed by two transmission lines, i.e., the primary winding 10 includes a first primary transmission line 131 and a second primary transmission line 132. The first primary transmission line 131 forms the first primary coil 11 and the second primary transmission line 132 forms the second primary coil 12. The secondary winding 20 is formed by a single transmission line, i.e., the secondary winding 20 includes a secondary transmission line 23, one part of which forms the first secondary coil 21 and the other part forms the second secondary coil 22.

In a specific embodiment, the first primary transmission line 131 includes a first end and a second end, the second primary transmission line 132 includes a third end and a fourth end, and the second end of the first primary transmission line 131 is connected with the third end of the second primary transmission line 132. The first primary transmission line 131 forms the first primary coil 11; the second primary transmission line 132 forms the second primary coil 12. Starting from the second end of the first primary transmission line 131, the routing direction of the first primary coil 11 is the first direction, and starting from the third end of the second primary transmission line 132, the routing direction of the second primary coil 12 is the second direction; and the first direction and the second direction are opposite. For example, the first direction is counterclockwise and the second direction is clockwise, or the first direction is clockwise and the second direction is counterclockwise. The secondary winding 20 includes a secondary transmission line 23, one part of which forms the first secondary coil 21 and the other part forms the second secondary coil 22. Starting from the first end of the secondary transmission line 23, the routing direction of the first secondary coil 21 is the first direction, and starting from the second end of the secondary transmission line 23, the routing direction of the second secondary coil 22 is the second direction; and the first coupling coil and the second coupling coil are arranged away from each other.

In this embodiment, the first primary coil 11 and the first secondary coil 21 are coupled to form a first coupling coil, and the second primary coil 12 and the second secondary coil 22 are coupled to form a second coupling coil. The current direction of the side adjacent to the second coupling coil in the first coupling coil is opposite to that of the side adjacent to the first coupling coil in the second coupling coil, so the first coupling coil and the second coupling coil are arranged away from each other. Therefore, the coupling degree of the conversion transformer 103 is further improved, the push-pull power amplifier circuit 100 is enabled to support a larger bandwidth, and at the same time, the flexibility of the arrangement of the conversion transformer 103 on the substrate 200 can be further improved.

As shown in FIG. 4, in a specific embodiment, the primary winding 10 includes a primary transmission line 13, one part of which forms a first primary coil 11 and the other part forms a second primary coil 12. Starting from the first end of the primary transmission line 13, the routing direction of the first primary coil 11 is the first direction, and starting from the second end of the primary transmission line 13, the routing direction of the second primary coil 12 is the second direction. The secondary winding 20 includes a first secondary transmission line 231 and a second secondary transmission line 232, and the first secondary transmission line 231 includes a first end and a second end. The second primary transmission line 132 includes a third end and a fourth end. The first secondary transmission line 231 forms the first secondary coil 21, and the second secondary transmission line 232 forms the second secondary coil 22. Starting from the second end of the first secondary transmission line 231, the routing direction of the first secondary coil 21 is the first direction, and starting from the third end of the second secondary transmission line 232, the routing direction of the second secondary coil 22 is the second direction. The first direction and the second direction are the same, and the first coupling coil and the second coupling coil are adjacent to each other.

In a specific embodiment, since the first direction and the second direction are the same, the current of the side adjacent to the second coupling coil in the first coupling coil and the current of the side adjacent to the first coupling coil in the second coupling coil are superimposed on each other. Therefore, by arranging the first coupling coil and the second coupling coil adjacent to each other, not only can the occupied area of the conversion transformer 103 on the substrate 200 be reduced, but also the coupling degree between the primary winding 10 and the secondary winding 20 be further improved, thereby improving the overall coupling degree of the conversion transformer 103 in the push-pull power amplifier circuit 100, so that the push-pull power amplifier circuit 100 can support a larger bandwidth.

In this embodiment, starting from the first end of the primary transmission line 13, the routing direction of the first primary coil 11 is the first direction, and starting from the second end of the primary transmission line 13, the routing direction of the second primary coil 12 is the second direction; and the first direction and the second direction are the same. For example, the first direction is clockwise and the second direction is clockwise. Alternatively, the first direction is counterclockwise and the second direction is counterclockwise. The first secondary transmission line 231 includes a first end and a second end. The second primary transmission line 132 includes a third end and a fourth end. The first secondary transmission line 231 forms the first secondary coil 21 and the second secondary transmission line 232 forms the second secondary coil 22. Starting from the second end of the first secondary transmission line 231, the routing direction of the first secondary coil 21 is the first direction, and starting from the third end of the second secondary transmission line 232, the routing direction of the second secondary coil 22 is the second direction; the first direction and the second direction are the same. The first primary coil 11 and the first secondary coil 21 are coupled to form the first coupling coil, the second primary coil 12 and the second secondary coil 22 are coupled to form a second coupling coil. Therefore, while reducing the occupied area of the conversion transformer 103, the coupling degree of the conversion transformer 103 can be improved, so that the push-pull power amplifier circuit 100 can support a larger bandwidth. In this way, the problem that the design of the transformer in the push-pull amplifier is difficult to give consideration to both the area and performance of the transformer because of the restriction of the area or number of layers of the substrate 200 is solved.

In a specific embodiment, the first direction is counterclockwise and the second direction is clockwise, or the first direction is clockwise and the second direction is counterclockwise, as long as the first direction and the second direction are two opposite routing directions on the substrate 200.

In an embodiment, as shown in FIG. 7, the push-pull power amplifier circuit 100 further includes a first differential amplifier branch 101 and a second differential amplifier branch 102. The first end of the primary winding 10 is connected with the output end of the first differential amplifier branch 101, and the second end of the primary winding 10 is connected with the output end of the second differential amplifier branch 102. The first end of the secondary winding 20 is connected with the signal output end Vout, and the second end of the secondary winding 20 is connected with the ground or the power supply. The first differential amplifier branch 101 is configured to amplify the first RF signal and output the first RF amplified signal to the first end of the primary winding 10, and the second differential amplifier branch 102 is configured to amplify the second RF signal and output the second RF amplified signal to the second end of the primary winding 10.

In this embodiment, the first differential amplifier branch 101 receives the first RF signal, amplifies the first RF signal, and outputs the first RF amplified signal to the first end of the primary winding 10 in the conversion transformer 103. The second differential amplifier branch 102 receives the second RF signal, amplifies the second RF signal, and outputs the second RF amplified signal to the second end of the primary winding 10 in the conversion transformer 103. In the conversion transformer 103, the first RF amplified signal and the second RF amplified signal are converted and synthesized, and the RF amplified signal is output to the later stage circuit.

In this embodiment, since the first end of the primary winding 10 is connected with the output end of the first differential amplifier branch 101, the second end of the primary winding 10 is connected with the output end of the second differential amplifier branch 102. The first end of the secondary winding 20 is connected to the signal output end Vout, and the second end of the secondary winding 20 is connected to the ground or the power supply. Therefore, when the routing direction of the first primary coil 11 is opposite to that of the second primary coil 12, the current direction of the side adjacent to the second coupling coil in the first coupling coil is opposite to that of the side adjacent to the first coupling coil in the second coupling coil. Therefore, by arranging the first coupling coil and the second coupling coil away from each other, the situation that the coupling degree between the primary winding 10 and the secondary winding 20 is affected by the mutual cancellation of the current of the side adjacent to the second coupling coil in the first coupling coil and the current of the side adjacent to the first coupling coil in the second coupling coil can be avoided. When the routing direction of the first primary coil 11 is the same as that of the second primary coil 12, the current direction of the side adjacent to the second coupling coil in the first coupling coil is the same as that of the side adjacent to the first coupling coil in the second coupling coil. Therefore, by arranging the first coupling coil and the second coupling coil adjacent to each other, not only can the occupied area of the conversion transformer 103 on the substrate 200 be reduced, but also the coupling degree between the primary winding 10 and the secondary winding 20 be further improved because the current of the side adjacent to the second coupling coil in the first coupling coil and the current of the side adjacent to the first coupling coil in the second coupling coil are superimposed on each other.

In an embodiment, as shown in FIG. 7, the first differential amplifier branch 101 includes a first amplifier M1, and the second differential amplifier branch 102 includes a second amplifier m2. The first amplifier M1 is connected with the first end of the primary winding 10, the second amplifier M2 is connected to the second end of the primary winding 10. The first amplifier M1 is configured to amplify the first RF signal and output the first RF amplified signal to the first end of the primary winding 10. The second amplifier M2 is configured to amplify the second RF signal and output the second RF amplified signal to the second end of the primary winding 10.

In a specific embodiment, the first differential amplifier branch 101 includes a first amplifier M1. The first amplifier M1 includes at least a first amplifier transistor (not shown in the figures). Alternatively, the first amplifier transistor is a BJT transistor (for example, an HBT transistor) or a field effect transistor. For example, the input end of the first amplifier M1 is the base of BJT transistor or the gate of field effect transistor, and the output end of the first amplifier M1 is the collector or the source of field effect transistor.

In a specific embodiment, the second differential amplifier branch 102 includes a second amplifier M2. The second amplifier M2 includes a second amplifier transistor (not shown in the figures). Optionally, the second amplification transistor includes at least one BJT transistor (e.g., HBT transistor) or a field effect transistor. For example, the input end of the second amplifier M2 is the base of the BJT transistor or the gate of the field effect transistor, and the output end of the second amplifier M2 is the collector of the BJT transistor or the source of the field effect transistor.

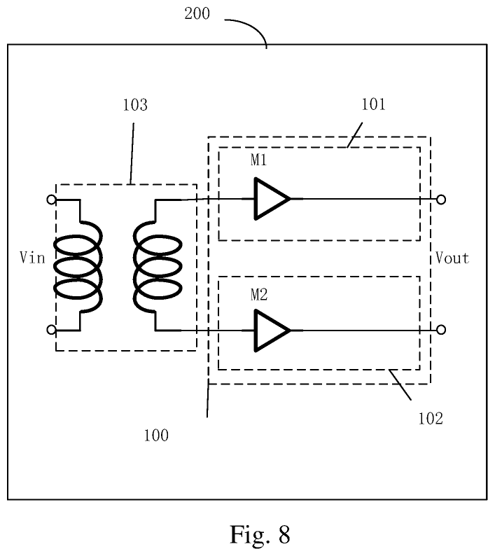

In an embodiment, as shown in FIG. 8, the push-pull power amplifier circuit 100 further includes a first differential amplifier branch 101 and a second differential amplifier branch 102. The first end of the secondary winding 20 is connected with the input end of the first differential amplifier branch 101, and the second end of the secondary winding 20 is connected with the input end of the second differential amplifier branch 102. The first end of the primary winding 10 is connected with the signal input end Vin, and the second end of the primary winding 10 is connected with the ground. The first differential amplifier branch 101 is configured to amplify the first RF signal and output the first RF amplified signal, and the second differential amplifier branch 102 is configured to amplify the second RF signal and output the second RF amplified signal. Understandably, in this embodiment, the conversion transformer 103 is used as a pre-stage conversion transformer 103 of the push-pull power amplifier circuit 100.

In this embodiment, since the first end of the primary winding 10 is connected with the output end of the first differential amplifier branch 101, the second end of the primary winding 10 is connected with the output end of the second differential amplifier branch 102. The first end of the secondary winding 20 is connected to the signal output end Vout, and the second end of the secondary winding 20 is connected to the ground or the power supply. Therefore, the first end of the secondary winding 20 is connected with the input end of the first differential amplifier branch 101, and the second end of the secondary winding 20 is connected with the input end of the second differential amplifier branch 102. The first end of the primary winding 10 is connected with the signal input terminal Vin, and the second end of the primary winding 10 is connected with the ground. Therefore, when the routing direction of the first primary coil 11 is opposite to that of the second primary coil 12, the current direction of the side adjacent to the second coupling coil in the first coupling coil is opposite to that of the side adjacent to the first coupling coil in the second coupling coil. Therefore, by arranging the first coupling coil and the second coupling coil away from each other, the situation that the coupling degree between the primary winding 10 and the secondary winding 20 is affected by the mutual cancellation of the current of the side adjacent to the second coupling coil in the first coupling coil and the current of the side adjacent to the first coupling coil in the second coupling coil can be avoided. When the routing direction of the first primary coil 11 is the same as that of the second primary coil 12, the current direction of the side adjacent to the second coupling coil in the first coupling coil is the same as that of the side adjacent to the first coupling coil in the second coupling coil. Therefore, by arranging the first coupling coil and the second coupling coil adjacent to each other, not only can the occupied area of the conversion transformer 103 on the substrate 200 be reduced, but also the coupling degree between the primary winding 10 and the secondary winding 20 be further improved because the current of the side adjacent to the second coupling coil in the first coupling coil and the current of the side adjacent to the first coupling coil in the second coupling coil are superimposed on each other.

In a specific embodiment, the first end of the primary winding 10 is connected with the signal input end Vin, and the second end of the primary winding 10 is connected with the ground, and is configured to receive the RF input signal of the signal input end Vin. The first end of the secondary winding 20 is connected with the input end of the first differential amplifier branch 101, and the second end of the secondary winding 20 is connected with the input end of the second differential amplifier branch 102. It is configured to convert the RF input signal, output the first RF signal to the first differential amplifier branch 101 and output the second RF signal to the second differential amplifier branch 102. In this embodiment, the conversion transformer 103 is used as a pre-stage conversion transformer 103 of the push-pull power amplifier circuit 100 to convert the RF input signal.

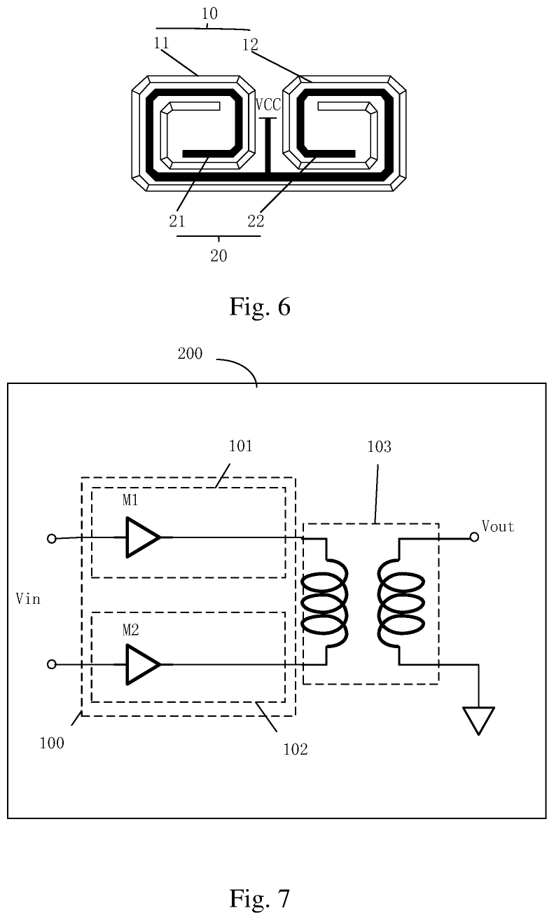

In an embodiment, as shown in FIG. 6, the RF front-end module further includes a feedback power VCC, if the current direction of the side adjacent to the second coupling coil in the first coupling coil is opposite to that of the side adjacent to the first coupling coil in the second coupling coil, the feedback power VCC is arranged between the first coupling coil and the second coupling coil, and the feedback power is coupled to the primary winding 10 via a transmission line.

In this embodiment, the RF front-end module further includes a feedback power VCC, and when the current direction of the side adjacent to the second coupling coil in the first coupling coil is opposite to that of the side adjacent to the first coupling coil in the second coupling coil, the first coupling coil and the second coupling coil are arranged away from each other, the feedback power VCC is arranged between the first coupling coil and the second coupling coil, and the feedback power VCC is coupled to the primary winding 10 via a transmission line. In this embodiment, when the current direction of the side adjacent to the second coupling coil in the first coupling coil is opposite to that of the side adjacent to the first coupling coil in the second coupling coil, the first coupling coil and the second coupling coil are arranged away from each other, the feedback power VCC is arranged between the first coupling coil and the second coupling coil. In this way, while improving the coupling degree of the conversion transformer 103 so that the push-pull power amplifier circuit 100 can support a larger bandwidth, the area between the first coupling coil and the second coupling coil can be reasonably utilized, thereby reducing the occupied area of the push-pull power amplifier circuit 100 on the substrate 200.

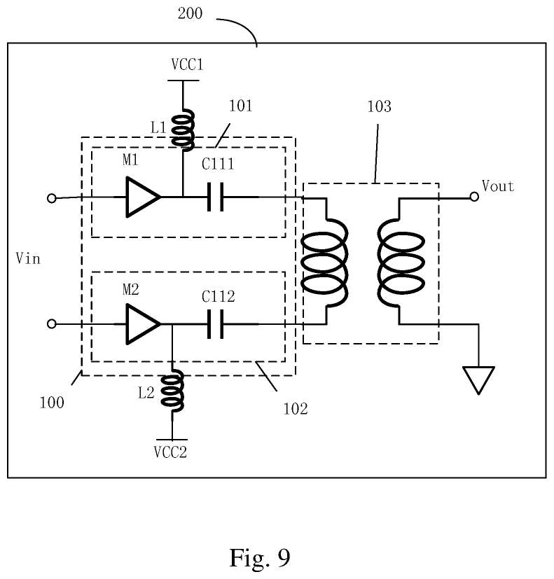

In a specific embodiment, referring to FIG. 9 below, the embodiment of the application further provides an RF front-end module, including a substrate 200 and a push-pull power amplifier circuit 100. The push-pull power amplifier circuit 100 includes a first differential amplifier branch 101, a second differential amplifier branch 102 and a conversion transformer 103. The conversion transformer 103 includes a primary winding 10 and a secondary winding 20 located on the same metal layer of substrate 200. The first differential amplifier branch 101 includes a first power amplifier and a first capacitor C111, and the second differential amplifier branch 102 includes a second power amplifier and a second capacitor C112. The output end of the first power amplifier is connected with a first end of the primary winding 10 via the first capacitor C111. The output end of the second power amplifier is connected with a second end of the primary winding 10 via the second capacitor C112. The first feedback power end is coupled to the output end of the first power amplifier via the first inductor, and the second feedback power end is coupled to the output end of the second power amplifier via the second inductor. In this embodiment, the output end of the first power amplifier is connected to the first end of the primary winding 10 of the conversion transformer 103 via the first capacitor C111. The output end of the second power amplifier is connected to the second end of the primary winding 10 of the conversion transformer 103 via the second capacitor C112. The first capacitor C111 and the second capacitor C112 can provide a part of impedance conversion. The first capacitor C111 and the second capacitor C112 together with the conversion transformer 103 participate in the impedance conversion of the push-pull power amplifier circuit 100 to achieve impedance matching. The push-pull power amplifier circuit 100 of this embodiment is a two-order matching push-pull power amplifier circuit 100. Compared with the one-order matching push-pull power amplifier circuit 100 (for example, the push-pull power amplifier circuit 100 with balun for impedance conversion alone), it can not only improve the bandwidth performance of the fundamental impedance of the push-pull power amplifier circuit 100, but also enable the turns ratio of the conversion transformer 103 to be adjusted more flexibly. In addition, since the DC signals provided by the first feedback power end and the second feedback power end in this embodiment do not need to pass through the coils in the conversion transformer 103, no DC signals pass through the coils in the conversion transformer 103. Compared with transmitting the feed signal provided by the feedback power to the first power amplifier and the second power amplifier through the conversion transformer 103, the width of the coil of the conversion transformer 103 in this embodiment can be designed to be narrower. Therefore, when the conversion transformer 103 is arranged in a single-layer substrate 200, the coupling degree between the primary winding 10 and secondary winding 20 of the conversion transformer can be further improved and the area of the conversion transformer 103 can be reduced, so as to further optimize the overall performance of the push-pull power amplifier circuit.

The primary winding 10 includes a first primary coil 11 and a second primary coil 12. The secondary winding 20 includes a first secondary coil 21 and a second secondary coil 22. The first primary coil 11 and first secondary coil 21 are coupled to form a first coupling coil, and the second primary coil 12 and second secondary coil 22 are coupled to form a second coupling coil. If the current direction of the side adjacent to the second coupling coil in the first coupling coil is the same as that of the side adjacent to the first coupling coil in the second coupling coil, the first coupling coil and the second coupling coil are arranged adjacent to each other. If the current direction of the side adjacent to the second coupling coil in the first coupling coil is opposite to the current direction of the side adjacent to the first coupling coil in the second coupling coil, the first coupling coil and the second coupling coil are arranged away from each other.

As an example, if the current direction of the side adjacent to the second coupling coil in the first coupling coil is the same as that of the side adjacent to the first coupling coil in the second coupling coil, the first coupling coil and the second coupling coil are arranged adjacent to each other. And, the minimum distance between the first coupling coil and the second coupling coil is about the width of one coil.

As an example, if the current direction of the side adjacent to the second coupling coil in the first coupling coil is opposite to that of the side adjacent to the first coupling coil in the second coupling coil, the first coupling coil and the second coupling coil are arranged away from each other. And, the maximum distance between the first coupling coil and the second coupling coil is about the width of four coils.

Specifically, the RF front-end module includes a substrate 200 and a push-pull power amplifier circuit 100 arranged on the substrate 200. Optionally, the substrate 200 is provided with at least two metal layers. At least one metal layer is used to place the primary winding 10 and the secondary winding 20 in the conversion transformer 103, and the other metal layer is used as a ground layer. The push-pull power amplifier circuit 100 is configured to amplify an RF input signal.

And, the primary winding 10 and the secondary winding 20 are arranged on the same metal layer of the substrate 200. For example, the substrate 200 in this embodiment includes a first metal layer and a second metal layer, and both the primary winding 10 and the secondary winding 20 are arranged on the first metal layer, and the second metal layer is used as a ground layer; the primary winding 10 includes a first primary coil 11 and a second primary coil 12, and the secondary winding 20 includes a first secondary coil 21 and a second secondary coil 22. The first primary coil 11 and first secondary coil 21 are coupled to form a first coupling coil, the second primary coil 12 and second secondary coil 22 are coupled to form a second coupling coil; and the first coupling coil and second coupling coil form a double coupling coil. Traditionally, the primary winding 10 and the secondary winding 20 are directly arranged on different metal layers of the substrate 200, and only a coupling coil is formed between the primary winding 10 and the secondary winding 20. In contrast, for the conversion transformer 103 in the push-pull power amplifier circuit 100 provided by the present application, by arranging the primary winding 10 and the secondary winding 20 on the first metal layer and forming a double coupling coil, not only can the occupied area and the number of layers on the substrate 200 be reduced, but also the overall performance applied to the push-pull power amplifier circuit 100 can be improved.

As an example, optionally, the number of turns of the first primary coil 11, the number of turns of the second primary coil 12, the number of turns of the first secondary coil 21 and the number of turns of the second secondary coil 22 may be adjusted according to actual needs. For example, according to the impedance conversion in the push-pull power amplifier circuit 100, the turns ratio of the first primary coil 11 and the second primary coil 12 to the first secondary coil 21 and the second secondary coil 22 is adjusted.

In a specific embodiment, when the current direction of the side adjacent to the second coupling coil in the first coupling coil is the same as that of the side adjacent to the first coupling coil in the second coupling coil, the current of the side adjacent to the second coupling coil in the first coupling coil and the current of the side adjacent to the first coupling coil in the second coupling coil are superimposed on each other. Therefore, by arranging the first coupling coil and the second coupling coil adjacent to each other, not only can the occupied area of the conversion transformer 103 on the substrate 200 be reduced, but also the coupling degree between the primary winding 10 and the secondary winding 20 can be further improved. Thereby improving the coupling degree and overall performance of the conversion transformer 103 applied to the push-pull power amplifier circuit 100, and enabling the push-pull power amplifier circuit 100 to support a larger bandwidth. Furthermore, it solves the problem that the design of transformer in push-pull amplifier is difficult to give consideration to both transformer area and performance because of the restriction of area or layer of the substrate 200.

In another specific embodiment, when the current direction of the side adjacent to the second coupling coil in the first coupling coil is opposite to that of the side adjacent to the first coupling coil in the second coupling coil, the current of the side adjacent to the second coupling coil in the first coupling coil and the current of the side adjacent to the first coupling coil in the second coupling coil cancel each other out. Therefore, by arranging the first coupling coil and the second coupling coil away from each other, the mutual cancellation of currents can be avoided to affect the coupling degree between the primary winding 10 and the secondary winding 20. Thereby improving the coupling degree between the primary winding 10 and the secondary winding 20, and further improving the overall coupling degree of the conversion transformer 103 in the push-pull power amplifier circuit 100, so that the push-pull power amplifier circuit 100 can support a larger bandwidth.

It can be seen from this that the conversion transformer 103 in the push-pull power amplifier circuit 100 of the present application can determine the current direction of the side adjacent to the second coupling coil in the first coupling coil, and the positions of the first coupling coil and the second coupling coil are flexibly arranged according to the current direction of the side adjacent to the first coupling coil in the second coupling coil. It can also improve the coupling degree and design flexibility of the conversion transformer 103, so that the push-pull power amplifier circuit 100 can support a larger bandwidth.

In this embodiment, for the push-pull power amplifier circuit 100, with the arrangement of the primary winding 10 and secondary winding 20 on the same metal layer of the substrate 200, the primary winding 10 and the secondary winding 20 form a separated double coupling coil. And the positions of the first coupling coil and second coupling coil can be flexibly arranged according to the current direction of the side adjacent to the second coupling coil in the first coupling coil and the current direction of the side adjacent to the first coupling coil in the second coupling coil. Therefore, while reducing the occupied area of the transformer in the push-pull amplifier, the coupling degree and design flexibility of the conversion transformer 103 can be improved, so that the push-pull power amplifier circuit 100 can support a larger bandwidth. In this way, the problem that the design of the transformer in the push-pull amplifier is difficult to give consideration to both the area and performance of the transformer because of the restriction of the area or number of layers of the substrate 200 is solved. And in this embodiment, the output end of the first power amplifier is connected to the first end of the primary winding 10 of the conversion transformer 103 via the first capacitor C111. The output end of the second power amplifier is connected to the second end of the primary winding 10 of the conversion transformer 103 via the second capacitor C112. Hence, the first capacitor C111 and the second capacitor C112 can provide a part of impedance conversion. That is, the first capacitor C111 and the second capacitor C112 together with the conversion transformer 103 participate in the impedance conversion of the push-pull power amplifier circuit 100 to achieve impedance matching. The push-pull power amplifier circuit 100 of this embodiment is a two-order matching push-pull power amplifier circuit 100. Compared with the one-order matching push-pull power amplifier circuit 100 (for example, the push-pull power amplifier circuit 100 with balun for impedance conversion alone), it can not only improve the bandwidth performance of the fundamental impedance of the push-pull power amplifier circuit 100, but also enable the turns ratio of the conversion transformer 103 to be adjusted more flexibly.

In this embodiment, the first feedback power VCC1 is coupled to the output end of the first power amplifier via the first inductor L1 to ensure that the first power amplifier can work regularly. The second feedback power VCC2 is coupled to the output end of the second power amplifier via the second inductor L2 to ensure that the second power amplifier can work regularly. Since the DC signals provided by the first feedback power end and the second feedback power end in this embodiment do not need to pass through the coils in the conversion transformer 103, no DC signals pass through the coils in the conversion transformer 103. Compared with transmitting the feed signal provided by the feedback power to the first power amplifier and the second power amplifier through the conversion transformer 103, the width of the coil of the conversion transformer 103 in this embodiment can be designed to be narrower. Therefore, when the conversion transformer 103 is arranged in a single-layer substrate 200, the coupling degree between the primary winding 10 and secondary winding 20 of the conversion transformer can be further improved and the area of the conversion transformer 103 can be reduced, so as to further optimize the overall performance of the push-pull power amplifier circuit.

It should be noted that the specific structure of the conversion transformer 103, coil routing mode, specific implementation mode and principle of this embodiment are completely the same as those in the above-mentioned embodiments, and thus no more description is provided herein to avoid redundancy.

The above embodiments are only used to illustrate the technical solutions of this application, but not to limit it. Although the application has been described in detail with reference to the aforementioned embodiments, those of ordinary skill in the art should understand that the technical solutions described in the aforementioned embodiments may still be modified, or some of the technical features may be equivalently replaced. However, these modifications or substitutions do not make the essence of the technical solutions deviate from the spirit and scope of the technical solutions of each embodiment of this application, and shall be included in the protection scope of this application.

1. An RF front-end module, comprising a substrate and a push-pull power amplifier circuit, wherein the push-pull power amplifier circuit comprises a conversion transformer, the conversion transformer comprises a primary winding and a secondary winding located on a same metal layer of the substrate;
the primary winding comprises a first primary coil and a second primary coil;
the secondary winding comprises a first secondary coil and a second secondary coil;
the first primary coil and the first secondary coil are coupled to form a first coupling coil, and the second primary coil and the second secondary coil are coupled to form a second coupling coil;
if a current direction of a side adjacent to the second coupling coil in the first coupling coil is the same as that of a side adjacent to the first coupling coil in the second coupling coil, the first coupling coil and the second coupling coil are arranged adjacent to each other; and
if a current direction of a side adjacent to the second coupling coil in the first coupling coil is opposite to that of a side adjacent to the first coupling coil in the second coupling coil, the first coupling coil and the second coupling coil are arranged away from each other.

2. The RF front-end module of claim 1, wherein both the primary winding and the secondary winding are windings formed by a single transmission line; or, one of the primary winding and the secondary winding is a winding formed by a single transmission line, and another one is a winding formed by connecting a first transmission line and a second transmission line; the first transmission line is positioned in the first coupling coil, and the second transmission line is positioned in the second coupling coil.

3. The RF front-end module of claim 2, wherein the primary winding comprises a primary transmission line, one part of the primary transmission line forms the first primary coil and another part forms the second primary coil; starting from a first end of the primary transmission line, a routing direction of the first primary coil is a first direction, and starting from a second end of the primary transmission line, a routing direction of the second primary coil is a second direction;
the secondary winding comprises a secondary transmission line, one part of the secondary transmission line forms the first secondary coil and another part forms the second secondary coil; starting from a first end of the secondary transmission line, a routing direction of the first secondary coil is the first direction, and starting from a second end of the secondary transmission line, a routing direction of a second secondary coil is the second direction; and
the first direction is opposite to the second direction, and the first coupling coil and the second coupling coil are arranged away from each other.

4. The RF front-end module of claim 2, wherein the primary winding comprises a first primary transmission line and a second primary transmission line; the first primary transmission line comprises a first end and a second end, the second primary transmission line comprises a third end and a fourth end, and the second end of the first primary transmission line is connected with the third end of the second primary transmission line; the first primary transmission line forms the first primary coil; and the second primary transmission line forms the second primary coil;
starting from the second end of the first primary transmission line, a routing direction of the first primary coil is a first direction, and starting from the third end of the second primary transmission line, a routing direction of the second primary coil is a second direction;
the secondary winding comprises a secondary transmission line, one part of the secondary transmission line forms the first secondary coil and another part forms the second secondary coil; starting from a first end of the secondary transmission line, a routing direction of the first secondary coil is the first direction, and starting from a second end of the secondary transmission line, a routing direction of a second secondary coil is the second direction; and
the first direction is opposite to the second direction, and the first coupling coil and the second coupling coil are arranged away from each other.

5. The RF front-end module of claim 4, wherein the second end of the first primary transmission line and the third end of the second primary transmission line are electrically connected by a first bonding wire.

6. The RF front-end module of claim 2, wherein the primary winding comprises a primary transmission line, one part of the primary transmission line forms the first primary coil and another part forms the second primary coil; starting from a first end of the primary transmission line, a routing direction of the first primary coil is a first direction, and starting from a second end of the primary transmission line, a routing direction of the second primary coil is a second direction;
the secondary winding comprises a first secondary transmission line and a second secondary transmission line, and the first secondary transmission line comprises a first end and a second end; the second secondary transmission line comprises a third end and a fourth end; the first secondary transmission line forms the first secondary coil, and the second secondary transmission line forms the second secondary coil; starting from the second end of the first secondary transmission line, a routing direction of the first secondary coil is a first direction, starting from the third end of the second secondary transmission line, a routing direction of the second secondary coil is a second direction; and
the first direction and the second direction are the same, and the first coupling coil and the second coupling coil are arranged adjacent to each other.

7. The RF front-end module of claim 6, wherein the second end of the first secondary transmission line and the third end of the second secondary transmission line are electrically connected by a second bonding wire.

8. The RF front-end module of claim 3, wherein the first direction is clockwise and the second direction is counterclockwise; or the first direction is counterclockwise and the second direction is clockwise.

9. The RF front-end module of claim 1, wherein the push-pull power amplifier circuit further comprises a first differential amplifier branch and a second differential amplifier branch;
the first end of the primary winding is connected with an output end of the first differential amplifier branch, and the second end of the primary winding is connected with an output end of the second differential amplifier branch; and
the first end of the secondary winding is connected with a signal output end, and the second end of the secondary winding is connected with a ground end or a power supply end.

10. The RF front-end module of claim 1, wherein the push-pull power amplifier circuit further comprises a first differential amplifier branch and a second differential amplifier branch;
the first end of the secondary winding is connected with an input end of the first differential amplifier branch, and the second end of the secondary winding is connected an input end of the second differential amplifier branch; and
the first end of the primary winding is connected with a signal input end, and the second end of the primary winding is connected with a ground end or a power supply end.

11. The RF front-end module of claim 1, wherein the RF front-end module further comprises a feedback power;
if the current direction of a side adjacent to the second coupling coil in the first coupling coil is opposite to that of a side adjacent to the first coupling coil in the second coupling coil, the feedback power is arranged between the first coupling coil and the second coupling coil, and is coupled to the primary winding through a transmission line.

12. An RF front-end module, comprising a substrate and a push-pull power amplifier circuit, wherein the push-pull power amplifier circuit comprises a first differential amplifier branch, a second differential amplifier branch and a conversion transformer;
the conversion transformer comprises a primary winding and a secondary winding located on a same metal layer of the substrate;
the first differential amplifier branch comprises a first power amplifier and a first capacitor, and the second differential amplifier branch comprises a second power amplifier and a second capacitor;
an output end of the first power amplifier is connected with a first end of the primary winding via the first capacitor; an output end of the second power amplifier is connected with a second end of the primary winding via the second capacitor;
a first feedback power end is coupled to the output end of the first power amplifier via a first inductor, and a second feedback power end is coupled to the output end of the second power amplifier via a second inductor;
the primary winding comprises a first primary coil and a second primary coil;
the secondary winding comprises a first secondary coil and a second secondary coil;
the first primary coil and the first secondary coil are coupled to form a first coupling coil, and the second primary coil and the second secondary coil are coupled to form a second coupling coil;
if a current direction of a side adjacent to the second coupling coil in the first coupling coil is the same as that of a side adjacent to the first coupling coil in the second coupling coil, the first coupling coil and the second coupling coil are arranged adjacent to each other; and
if a current direction of a side adjacent to the second coupling coil in the first coupling coil is opposite to that of a side adjacent to the first coupling coil in the second coupling coil, the first coupling coil and the second coupling coil are arranged away from each other.

13. The RF front-end module of claim 12, wherein both the primary winding and the secondary winding are windings formed by a single transmission line; or, one of the primary winding and the secondary winding is a winding formed by a single transmission line, and another one is a winding formed by connecting a first transmission line and a second transmission line; the first transmission line is positioned in the first coupling coil, and the second transmission line is positioned in the second coupling coil.

14. The RF front-end module of claim 4, wherein the first direction is clockwise and the second direction is counterclockwise; or the first direction is counterclockwise and the second direction is clockwise.

15. The RF front-end module of claim 6, wherein the first direction is clockwise and the second direction is counterclockwise; or the first direction is counterclockwise and the second direction is clockwise.
